(19) United States
(12) Patent Application Publication
(10) Pub. No.: US 2026/0282954 A1
(43) Pub. Date: Sep. 17, 2026

(54) ELECTRONIC DEVICE

(71) Applicants: Innolux Corporation, Miaoli County (TW); nD-HI Technologies Lab, Inc., Taipei City (TW)

(72) Inventors: Szu-Yen Yu, Miaoli County (TW); Shu-Hsien Wu, Miaoli County (TW); Shu-Fen Ku, Miaoli County (TW); Chih-Chao Chuang, Miaoli County (TW); Ho-Ming Tong, Taipei City (TW); Ching-Yu Chu, Miaoli County (TW); Chun-Yu Chien, Miaoli County (TW); Cheng-En Cheng, Miaoli County (TW); Yeong-E Chen, Miaoli County (TW); Tong-Jung Wang, Miaoli County (TW)

(73) Assignees: Innolux Corporation, Miaoli County (TW); nD-HI Technologies Lab, Inc., Taipei City (TW)

(21) Appl. No.: 19/560,168

(22) Filed: Mar. 9, 2026

Related U.S. Application Data
(60) Provisional application No. 63/784,996, filed on Apr. 8, 2025.
(60) Provisional application No. 63/778,397, filed on Mar. 27, 2025.
(60) Provisional application No. 63/775,318, filed on Mar. 21, 2025.
(60) Provisional application No. 63/769,778, filed on Mar. 11, 2025.

(30) Foreign Application Priority Data
Nov. 6, 2025 (CN) 202511620223.2

(51) Int. Cl. H10W 70/60; H10W 40/20; H10W 42/00; H10W 70/63; H10W 70/695; H10W 90/10; H10W 90/00

(52) U.S. Cl. CPC H10W 70/614; H10W 40/233; H10W 40/235; H10W 42/121; H10W 70/635; H10W 70/695; H10W 90/10; H10W 90/724

(57) ABSTRACT

The present disclosure provides an electronic device including an interposer including a connection substrate including a substrate layer and through vias penetrating thereof, and a first and second circuit structures respectively on first and second surfaces of the substrate layer, and each including first wirings electrically connected to each other through first through vias among the through vias and second wirings thermally coupled to each other through second through vias among the through vias, an electronic unit disposed on and electrically connected to the interposer, and a heat dissipation element unit disposed on the interposer at opposite sides of the interposer, and is in contact and thermally coupled to the second wirings and the second through vias.

### CROSS-REFERENCE TO RELATED APPLICATION

This application claims the priority benefits of U.S. provisional application serial no. 63/769,778, filed on March 11, 2025, U.S. provisional application serial no. 63/784,996, filed on April 08, 2025, U.S. provisional application serial no. 63/778,397, filed on March 27, 2025, U.S. provisional application serial no. 63/775,318, filed on March 21, 2025, and China application serial no. 202511620223.2, filed on November 6, 2025. The entirety of each of the above-mentioned patent applications is hereby incorporated by reference herein and made a part of this specification.

### BACKGROUND

### Technical Field

The present disclosure relates to an electronic device, particularly an electronic device with improved reliability.

### Description of Related Art

In current semiconductor packaging technology, mounting electronic units with different functions on the same substrate is one of the manners to enhance the performance of electronic devices. As electronic devices continue to be developed toward lighter, thinner, shorter, and smaller dimensions and performance requirements for electronic devices from users continue to increase, the density of electronic units mounted on the substrates is also increasing. Therefore, 2.5D packaging technology is gradually receiving attention to meet the demand for more input/output pads (I/O pads) or to meet the demand for continuously increasing interconnection density. However, as semiconductor technology continues to advance, the interposer used in 2.5D packaging technology still faces challenges in terms of reliability and/or heat dissipation efficiency. Therefore, those skilled in the art continue to improve the interposer to meet current or future demands.

### SUMMARY

The present disclosure provides an electronic device with improved reliability.

According to an embodiment of the present disclosure, an electronic device includes an interposer, at least one electronic unit, and a first heat dissipation element. The interposer includes a connection substrate and a first circuit structure and a second circuit structure. The connection substrate includes a substrate layer and through vias penetrating through a first surface and a second surface of the substrate layer opposite to each other in a first direction. The first circuit structure and the second circuit structure are respectively disposed on the first surface and the second surface and each includes a first wiring structure electrically connected to each other through at least one first through via among the through vias and a second wiring structure thermally coupled to each other through at least one second through via among the through vias. The electronic unit is disposed on the interposer and electrically connected to the interposer. The first heat dissipation element is disposed on side surfaces of the interposer opposite to each other in a second direction different from the first direction, and the first heat dissipation element is in contact with and thermally coupled to the second wiring structure and the second through via.

Based on the above, in the embodiments of the disclosure, each of the first circuit structure and the second circuit structure includes the second wiring structure thermally coupled to each other through the second through via among the through vias, and the first heat dissipation element disposed on the side surfaces of the interposer is in contact with and thermally coupled to the second wiring structure and the second through via, which is beneficial to enhancing the heat dissipation efficiency of the electronic device.

To make the foregoing features and advantages of the disclosure more comprehensible, embodiments are specifically provided below and described in detail with reference to the accompanying drawings as follows.

### BRIEF DESCRIPTION OF THE DRAWINGS

The drawings are included to provide a further understanding of the disclosure, and the drawings are incorporated in and constitute a part of this specification. The drawings illustrate embodiments of the disclosure and, together with the description, serve to explain the principles of the disclosure.

FIG. 1 is a schematic cross-sectional view illustrating an electronic device according to an embodiment of the present disclosure.

FIG. 2 is a schematic enlarged cross-sectional view showing the planarization layer of FIG. 1 according to an embodiment of the present disclosure.

FIG. 3 is a schematic enlarged cross-sectional view showing the planarization layer of FIG. 1 according to another embodiment of the present disclosure.

FIG. 4 is a schematic cross-sectional view illustrating an interposer according to another embodiment of the present disclosure.

FIG. 5 is a schematic cross-sectional view illustrating an electronic device according to another embodiment of the present disclosure.

FIG. 6 is a schematic enlarged cross-sectional view showing the electronic element and the adhesive layer of FIG. 5 according to an embodiment of the present disclosure.

FIGS. 7A-7C are schematic enlarged cross-sectional views of the adhesive layer shown in FIG. 5 according to various embodiments.

FIG. 8A and FIG. 8B are schematic perspective views of the first heat dissipation element shown in FIG. 1 according to various embodiments.

### DESCRIPTION OF THE EMBODIMENTS

The disclosure may be understood by referring to the following detailed description together with the accompanying drawings. It should be noted that, in order to enable readers to easily understand and for the simplicity of the drawings, multiple drawings in the disclosure merely show a part of the package structure, and specific components in the drawings are not drawn according to actual scale. In addition, the number and dimensions of each component in the drawings are merely for illustration and are not used to limit the scope of the disclosure. For example, for clarity, the relative dimensions, thickness, and positions of each film layer, region, and/or structure may be reduced or enlarged.

Certain terms are used throughout the specification and the appended claims of the disclosure to refer to specific components. Persons skilled in the art should understand that electronic device manufacturers may refer to the same component by different names. This document does not intend to distinguish between components that have the same function but different names. In the following specification and claims, terms such as "have" and "include" are open-ended terms, and therefore should be interpreted to mean "include but not limited to...".

In this document, "one component is set on another component" is for the convenience of describing the relative position between the component and the another component, and is not used to limit the process steps or sequence of the component and the another component.

The directional terms mentioned in this document, such as: "upper", "lower", "front", "rear", "left", "right", are merely references to the directions of the accompanying drawings. Therefore, the directional terms used are for illustration and are not used to limit the disclosure. It should be understood that when a component or film layer is referred to as being set "on" another component or film layer or "connected" to another component or film layer, the component or film layer may be directly on the another component or film layer or directly connected to the another component or film layer, or there are inserted components or film layers between the two (non-direct situation). Conversely, when a component or film layer is referred to as being "directly" "on" another component or film layer or "directly connected" to another component or film layer, there are no inserted components or film layers between the two. In addition, when a component or film layer is referred to as overlapping with another component, the component or film layer at least partially overlaps with the another component or film layer.

The terms "about", "approximately", "substantially", or "roughly" mentioned in this document generally represent falling within a 10% range of a given value or range, or represent falling within a 5%, 3%, 2%, 1%, or 0.5% range of a given value or range. In addition, the phrases "a given range is from a first value to a second value", "a given range falls within the range from a first value to a second value" indicate that the given range includes the first value, the second value, and other values therebetween.

In some embodiments of the disclosure, terms regarding bonding and connection such as "connect", "interconnect", unless specifically defined, may refer to two structures being in direct contact, or may also refer to two structures not being in direct contact, wherein other structures are set between the two structures. Terms regarding bonding and connection may also include situations where both structures are movable, or both structures are fixed. In addition, the terms "electrically connect" and "couple" include any direct and indirect electrical connection manners.

In the disclosure, the measurement methods for thickness, length and width may optionally adopt optical microscope (OM) and/or scanning electron microscope (SEM) measurement, but are not limited thereto. In addition, any two values or directions used for comparison may have certain errors. If a first value equals a second value, it implies that there may be an error of about 10% between the first value and the second value.

The electronic device in the disclosure may exemplify apply to wafer-level package (WLP), for example, including, but not limited to, Chip-on-Wafer-on-Substrate (CoWoS) technology, or may apply to panel-level package (PLP), for example, including, but not limited to Chip-on-Panel-on-Substrate (CoPoS) technology. In some embodiments, the electronic device in the disclosure may include structures formed by a chip-last process or a chip-first process, but is not limited thereto. The electronic device described in the disclosure may apply to high-speed computing modules, power modules, semiconductor package devices, optical communication modules, display devices, light-emitting devices, backlight devices, antenna devices, sensing devices or splicing devices, but the disclosure is not limited thereto.

The following exemplifies exemplary embodiments of the disclosure, in which the same component symbols are used in the drawings and description to represent the same or similar parts.

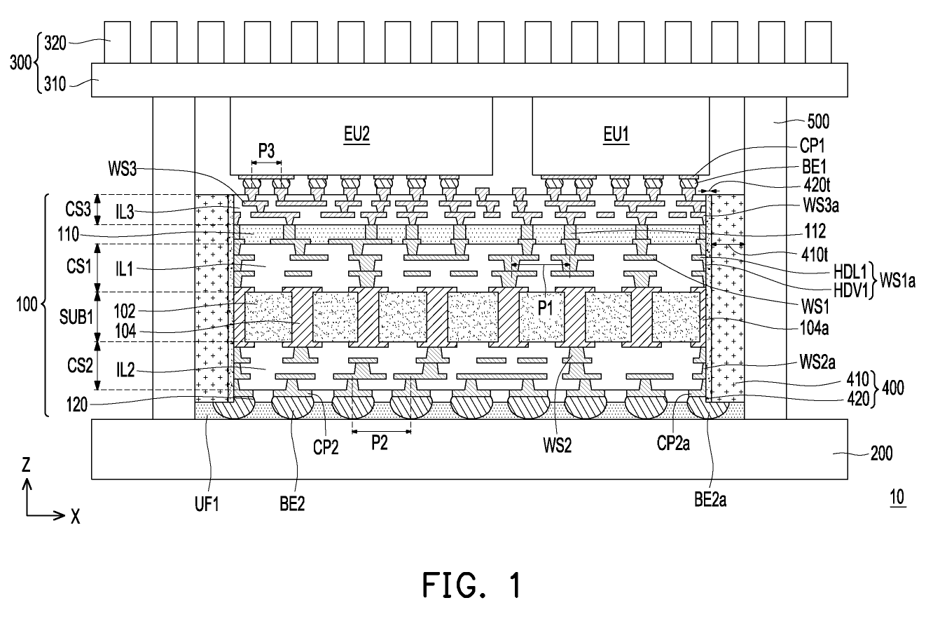

First, referring to FIG. 1, the electronic device 10 includes an interposer 100, at least one electronic unit EU1 or EU2, and a first heat dissipation element 400.

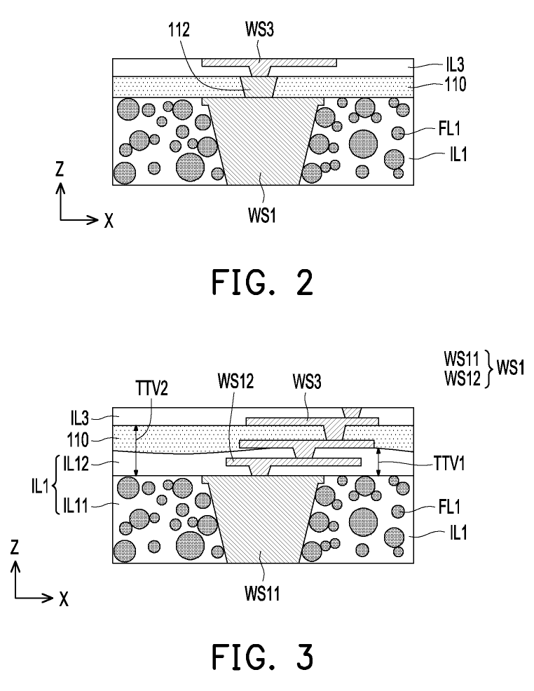

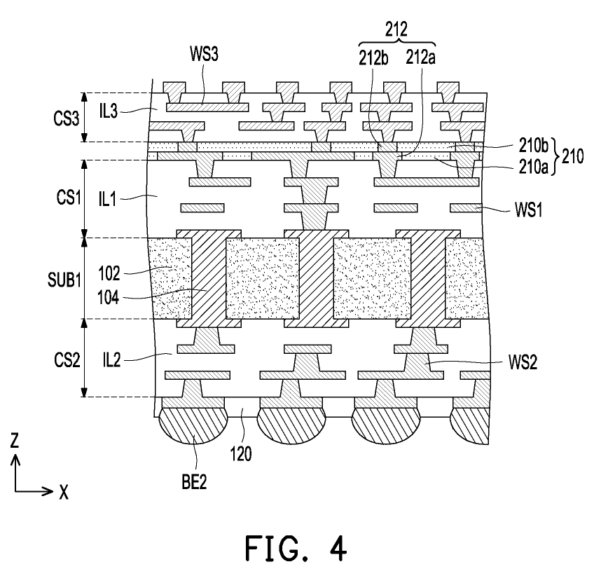

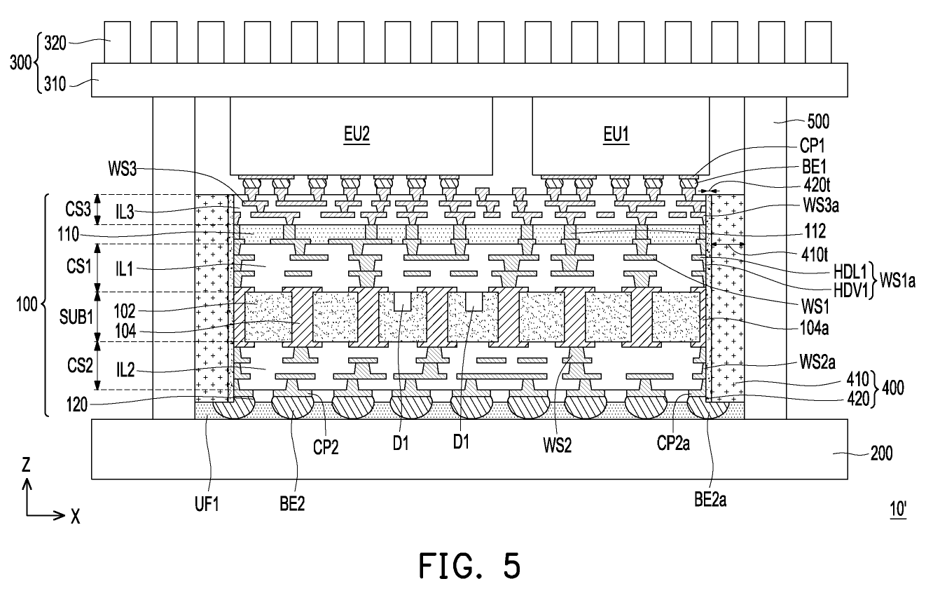

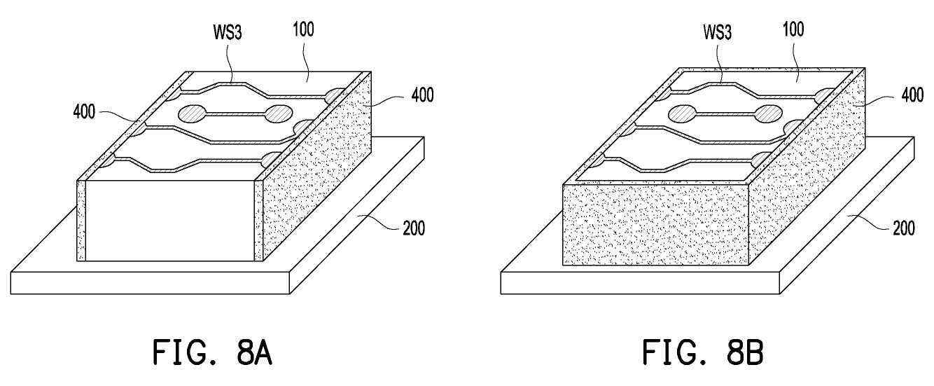

FIG. 1 is a schematic cross-sectional view illustrating an electronic device according to an embodiment of the present disclosure. FIG. 2 is a schematic enlarged cross-sectional view showing the planarization layer of FIG. 1 according to an embodiment of the present disclosure. FIG. 3 is a schematic enlarged cross-sectional view showing the planarization layer of FIG. 1 according to another embodiment of the present disclosure. FIG. 4 is a schematic cross-sectional view illustrating an interposer according to another embodiment of the present disclosure. FIGS. 8A and 8B are schematic perspective views of the first heat dissipation element shown in FIG. 1 according to various embodiments.

The interposer 100 includes a connection substrate SUB1 and a first circuit structure CS1 and a second circuit structure CS2. The connection substrate SUB1 includes a substrate layer 102 and through vias 104 penetrating through a first surface and a second surface of the substrate layer 102 opposite to each other in a first direction (e.g., Z direction). In some embodiments, the substrate layer 102 may include materials for core substrates, such as bismaleimide triazine (BT), FR4, epoxy resin or glass, but is not limited thereto. The through vias 104 may include any suitable conductive material such as metal, for example, copper (Cu), titanium (Ti), nickel (Ni), combinations or alloys of the above materials, but is not limited thereto.

In some embodiments, the connection substrate SUB1 may have a panel-level size. For example, the area of the connection substrate SUB1 may include 5 cm x 5 cm, 10 cm x 10 cm, 30 cm x 30 cm, 50 cm x 50 cm, 70 cm x 70 cm or any suitable size, but is not limited thereto. In the case where the connection substrate SUB1 has a panel-level size, the connection substrate SUB1 may be applied to fan out panel level package (FOPLP) process. Since FOPLP adopts the connection substrate SUB1 having a panel-level size, the production capacity can be significantly enhanced compared to WLP. Also, the connection substrate SUB1 having a panel-level size may have a rectangular profile, which may also significantly enhance the utilization rate of the connection substrate SUB1 compared to WLP.

The first circuit structure CS1 and the second circuit structure CS2 are respectively disposed on the first and second surfaces of the substrate layer 102, and each includes wiring structures WS1, WS2 (being referred to as first wiring structures) electrically connected to each other through at least one through via 104 (being referred to as first through via) among the through vias 104, and wiring structures WS1a, WS2a (being referred to as second wiring structures) thermally coupled to each other through at least one through via 104a (being referred to as second through via) among the through vias 104. The wiring structures WS1, WS2 and the wiring structures WS1a, WS2a may include any suitable conductive material such as metal, for example, Cu, Ti, Ni, combinations or alloys of the above materials, but is not limited thereto.

In some embodiments, the first circuit structure CS1 may include an insulation layer IL1 in which the wiring structure WS1 and the wiring structure WS1a are disposed, and the second circuit structure CS2 may include an insulation layer IL2 in which the wiring structure WS2 and the wiring structure WS2a are disposed. In some embodiments, the insulation layer IL1 and the insulation layer IL2 may each include insulation layers alternately stacked along the Z direction, but is not limited thereto. The insulation layer IL1 and the insulation layer IL2 may each include organic material or inorganic material. The organic material may include polyimide (PI), poly-p-xylylene (also known as Parylene), benzocyclobutene (BCB), epoxy, polycarbonate (PC), polyethylene terephthalate (PET), polyethylene naphthalate (PEN), polymer or other suitable organic materials, but is not limited thereto. The inorganic material may include silicon oxide, silicon nitride, silicon oxynitride or other suitable inorganic materials, but is not limited thereto.

In some embodiments, the wiring structures WS1, WS2 may each include conductive patterns/conductive layers respectively formed in the insulation layer IL1 and the insulation layer IL2 and alternately stacked along the Z direction, and conductive vias connecting the conductive patterns/conductive layers. In some embodiments, the wiring structures WS1a, WS2a may each include heat dissipation patterns/heat dissipation layers respectively formed in the insulation layer IL1 and the insulation layer IL2 and alternately stacked along the Z direction, and heat dissipation vias connecting the heat dissipation patterns/heat dissipation layers. For example, the wiring structures WS1a, WS2a may include heat dissipation layers HDL1 and heat dissipation vias HDV1 disposed in the insulation layers IL1, IL2, wherein the heat dissipation layers HDL1 are thermally coupled to the heat dissipation vias HDV1 and each includes a sidewall exposed at a side surface of the interposer 100 on which the first heat dissipation element 400 is disposed. In some embodiments, the wiring structures WS1, WS2 and the wiring structures WS1a, WS2a may include the same material, that is, the wiring structures WS1, WS2 and the wiring structures WS1a, WS2a may include conductive materials (such as metal materials) with good electrical conductivity and thermal conductivity.

At least one electronic unit EU1 or EU2 is disposed on and electrically connected to the interposer 100. In the present embodiment, the at least one electronic unit EU1 or EU2 may include electronic units EU1, EU2. The electronic units EU1, EU2 may include various electronic elements, such as passive elements, active elements, or combinations thereof. For example, the electronic units EU1, EU2 may include capacitors, resistors, inductors, variable capacitors, filters, diodes, transistors, sensors, micro-electro-mechanical system (MEMS) elements, system-on-chip (SoC), central processing units (CPU), graphics processing units (GPU), memories, logic dies, or combinations thereof, but are not limited thereto.

The first heat dissipation elements 400 are disposed on side surfaces of the interposer 100 that are opposite to each other in a second direction (e.g., X direction) different from the first direction. In some embodiments, the second direction may be perpendicular to the first direction. The first heat dissipation elements 400 are in contact with and thermally coupled to the wiring structures WS1a, WS2a and the through vias 104a. Accordingly, heat generated by the electronic unit EU1 or EU2 may be transferred to the outside through additional heat transfer paths. For example, heat generated by the electronic unit EU1 or EU2 may be transferred to the first heat dissipation elements 400 through the wiring structures WS1a, WS2a, and/or the through vias 104a, thereby helping to enhance the heat dissipation efficiency of the electronic device 10. In some embodiments, the first heat dissipation elements 400 may be disposed on two side surfaces of the interposer 100 that are opposite to each other in the X direction (as shown in FIGS. 1 and 8A). In other embodiments, the first heat dissipation elements 400 may be disposed on two side surfaces of the interposer 100 that are opposite to each other in the X direction and on two side surfaces that are opposite to each other in the Y direction (as shown in FIGS. 1 and 8B), to surround the interposer 100, to enhance the heat dissipation efficiency of the electronic device 10.

In some embodiments, the side surfaces of the interposer 100 on which the first heat dissipation elements 400 are disposed may expose a portion of the wiring structures WS1a, WS2a and the through vias 104a, and the first heat dissipation elements 400 may directly contact the portions of the wiring structures WS1a, WS2a and the through vias 104a. Namely, the wiring structures WS1a, WS2a and the through vias 104a may be thermally coupled to the first heat dissipation elements 400 directly.

In some embodiments, the interposer 100 may further include a third circuit structure CS3 disposed above the first circuit structure CS1, wherein the third circuit structure CS3 may include a wiring structure WS3 electrically connecting the electronic units EU1, EU2 to the wiring structure WS1 and a wiring structure WS3a thermally coupled to the wiring structure WS1a. In the present embodiment, the wiring structure WS3a is in contact with and thermally coupled to the first heat dissipation elements 400. Accordingly, heat generated by the electronic unit EU1 or EU2 may be transferred to the outside through additional heat transfer paths. For example, heat generated by the electronic unit EU1 or EU2 may be transferred to the first heat dissipation elements 400 through the wiring structures WS1a, WS2a, WS3a, and/or the through vias 104a, thereby helping to enhance the heat dissipation efficiency of the electronic device 10.

In some embodiments, the third circuit structure CS3 may include an insulation layer IL3 in which the wiring structure WS3 and the wiring structure WS3a are disposed. In some embodiments, the insulation layer IL3 may include insulation layers alternately stacked along the Z direction, but is not limited thereto. In the present embodiment, the pitch (e.g., pitch P3) of the third wiring structure WS3 may be smaller than the pitch (e.g., pitch P1 or P2) of the wiring structure WS1 and/or the wiring structure WS2, to match the pitch of the connection pads CP1 of the electronic units EU1, EU2. In this embodiment, the insulation layer IL3 may include a material different from the insulation layers IL1 and IL2. For example, the insulation layers IL1 and IL2 may include organic materials, and the insulation layer IL3 may include inorganic materials. The connection pads CP1 may include any suitable conductive material.

In some embodiments, the third circuit structure CS3 may be electrically connected to the electronic units EU1, EU2 through bonding elements BE1. In some embodiments, the bonding elements BE1 may include solder balls. The material of the bonding elements BE1 may include tin-silver (SnAg), tin, silver, nickel, gold, copper, conductive adhesive, or other suitable conductive materials, but is not limited thereto.

In some embodiments, the first heat dissipation element 400 may include a heat dissipation layer 410 and an adjustment layer 420 disposed between the heat dissipation layer 410 and the interposer 100 in the second direction (e.g., X direction). The heat dissipation layer 410 may include a thermally conductive material with good thermal conductivity to help enhance the heat dissipation efficiency of the interposer 100. In some embodiments, the thermally conductive material may include materials such as diamond, silicon carbide (SiC), graphene, hexagonal boron nitride (hexagonal BN, h-BN), AlN, or beryllium oxide (BeO), but is not limited thereto. In the present embodiment, the adjustment layer 420 may serve as a coefficient of thermal expansion (CTE) adjustment layer to mitigate warpage caused by CTE mismatch due to stacking of different materials in the interposer 100, thereby helping to improve the reliability of the electronic device 10. For example, when the insulation layers IL1, IL2 and the substrate layer 102 include organic insulation materials, and the insulation layer IL3 stacked on the insulation layer IL1 includes inorganic insulation materials, the adjustment layer 420 may adopt a material with a CTE smaller than the overall CTE of the interposer 100 to help mitigate warpage caused by CTE mismatch, thereby improving the reliability of the electronic device 10. In this embodiment, the material of the adjustment layer 420 may include TiN, TiW, or a combination thereof. In some embodiments, the adjustment layer 420 may directly contact the side surface of the interposer 100 on which the first heat dissipation element 400 is disposed.

In the present embodiment, the overall CTE of the interposer 100 may be calculated in the following manner. The insulation layers IL1, IL2 and IL3 have respective volumes represented by V_{A1}, V_{A2} and V_{A3}, and respective CTE values represented by CTE_{A1}, CTE_{A2} and CTE_{A3}, while the wiring structures WS1, WS2 and WS3 have respective volumes represented by V_{B1}, V_{B2} and V_{B3}, and respective CTE values represented by CTE_{B1}, CTE_{B2} and CTE_{B3}. The substrate layer 102 of the connection substrate SUB1 has a volume of V_{C1}, and a CTE value of CTE_{C1}, while the through vias 104 of the connection substrate SUB1 has a volume of V_{C2}, and a CTE value of CTE_{C2}. The total volume of the interposer 100 may be the sum of V_{A1}, V_{A2}, V_{A3}, V_{B1}, V_{B2}, V_{B3}, V_{C1}, and V_{C2} (being referred to as Vₜₒₜₐₗ), and the overall CTE of the interposer 100 may be obtained through the following calculation:

((V_{A1}*CTE_{A1})+(V_{A2}*CTE_{A2})+(V_{A3}*CTE_{A3})+(V_{B1}*CTE_{B1})+(V_{B2}*CTE_{B2})+(V_{B3}*CTE_{B3})+(V_{C1}*CTE_{C1})+(V_{C2}*CTE_{C2}))/ total volume of the interposer 100 (Vₜₒₜₐₗ).

In some embodiments, the heat transfer coefficient (unit: W/mK) of the heat dissipation layer 410 may be greater than the heat transfer coefficient of the adjustment layer 420, to help enhance the heat dissipation efficiency of the electronic device 10. In some embodiments, the thickness 410t of the heat dissipation layer 410 in the second direction (e.g., X direction) may be greater than the thickness 420t of the adjustment layer 420 in the second direction, which is beneficial to enhancing the heat dissipation efficiency of the electronic device 10. According to some embodiments, the heat transfer coefficient of the adjustment layer 420 is different from (e.g., greater than or less than) the heat transfer coefficient of the wiring structure, to help enhance the heat dissipation efficiency of the electronic device 10. When the heat transfer coefficient of the adjustment layer 420 is less than the heat transfer coefficient of the wiring structure, the thickness of the adjustment layer 420 may be less than the thickness of the heat dissipation layer 410.

In some embodiments, the electronic device 10 may further include an external component 200 and a heat dissipation member 300. The external component 200 may be disposed below and electrically connected to the interposer 100. In some embodiments, the external component 200 may be a circuit substrate (e.g., a printed circuit board), but is not limited thereto. The heat dissipation member 300 may be disposed on and thermally coupled to the electronic units EU1, EU2. In some embodiments, the heat dissipation member 300 may include a heat dissipation substrate 310 and a heat dissipation structure 320 disposed on the heat dissipation substrate 310. The heat dissipation substrate 310 and the heat dissipation structure 320 may each include any suitable thermally conductive material. In the present embodiment, the heat dissipation structure 320 may be, for example, a heat dissipation fin having a fin-shaped structure.

In some embodiments, the electronic device 10 may further include bonding elements BE2 disposed between the interposer 100 and the external component 200. The bonding elements BE2 include at least one (also referred to as a first bonding element) electrically connecting the wiring structure WS2 of the second circuit structure CS2 to the external component 200 and at least another one (also referred to as a second bonding element, such as the bonding element BE2a shown in FIG. 1) thermally coupling the wiring structure WS2a of the second circuit structure CS2 to the external component 200, such that heat generated by the electronic unit EU1 or EU2 may be transferred to the outside through additional heat transfer paths, for example, heat generated by the electronic unit EU1 or EU2 may be transferred to the first heat dissipation element 400 and/or the external component 200 through the wiring structures WS1a, WS2a and WS3a and/or the through via 104a, thereby helping to enhance the heat dissipation efficiency of the electronic device 10. In some embodiments, the material of the bonding element BE2 may be the same as or different from the bonding element BE1.

In some embodiments, the electronic device 10 may further include an underfill UF1. The underfill UF1 may be disposed between the external component 200 and the interposer 100 and surround the bonding elements BE2, to ensure the connection path between the interposer 100 and the external component 200, thereby improving the reliability of the electronic device 10.

In the present embodiment, the interposer 100 may include a solder resist layer 120 formed below the second circuit structure CS2 and disposed between the underfill UF1 and the second circuit structure CS2. The solder resist layer 120 may cover the insulation layer IL2 and expose the connection pads CP2 of the wiring structure WS2 and the connection pads CP2a of the wiring structure WS2a, such that the bonding elements BE2 may have good contact with the surfaces of the connection pads CP2 and the connection pads CP2a exposed by the solder resist layer 120, helping to improve the reliability of the electronic device 10. The solder resist layer 120 may include an organic material or an inorganic material.

In the present embodiment, the bonding elements BE2a are in contact with and thermally coupled to the connection pads CP2a. In some embodiments, the bonding elements BE2a may include portions overlapping the first heat dissipation elements 400 in the first direction (e.g., the Z direction). In some embodiments, the portions of the bonding elements BE2a overlapping the first heat dissipation elements 400 are in direct contact with the first heat dissipation elements 400, which is beneficial to enhancing the heat dissipation efficiency of the electronic device 10. In some embodiments, the heat transfer coefficients of the bonding elements BE2a are greater than the heat transfer coefficients of the bonding elements BE2. In some embodiments, the bonding elements BE2a may form alloys with the connection pads CP2a and the first heat dissipation elements 400, respectively, but is not limited thereto.

In some embodiments, the electronic device 10 may further include a stiffener 500. The stiffener 500 may surround the side surfaces of the interposer 100 and may be disposed between the heat dissipation member 300 and the external component 200 in the first direction (e.g., the Z direction), wherein the first heat dissipation elements 400 may be disposed between the stiffener 500 and the interposer 100 in the second direction (e.g., the X direction). In some embodiments, the stiffener 500 may be in contact with and thermally coupled to the first heat dissipation elements 400 and the heat dissipation member 300, such that the heat generated by the electronic unit EU1 or EU2 may be laterally transferred to the first heat dissipation elements 400 through the wiring structures WS1a, WS2a and WS3a and/or the through vias 104a, and vertically transferred to the heat dissipation member 300 through the stiffener 500. In some other embodiments, the stiffener 500 may also contact and be thermally coupled to the external component 200, such that the heat generated by the electronic unit EU1 or EU2 may also be vertically transferred to the external component 200 through the stiffener 500, or the external component 200 may also transfer heat to the heat dissipation member 300 through the stiffener 500. In some embodiments, the stiffener 500 may be a stiffener ring surrounding the interposer 100. The stiffener 500 may include any suitable thermally conductive material, such as metal, conductive adhesive material or combinations thereof, such as copper, aluminum, thermal interface material or combinations thereof, so as to enhance the heat dissipation efficiency of the electronic device 10.

In some embodiments, the interposer 100 may include a planarization layer 110 disposed between the third circuit structure CS3 and the first circuit structure CS1, such that the third circuit structure CS3 may be formed on a layer with good flatness, thereby reducing the risk (e.g., short circuit) caused by the wiring structure WS3 in the third circuit structure CS3 being formed on an uneven surface. As shown in FIGS. 2 and 3, in the embodiment where the insulation layer IL1 contains fillers FL1 and causes the thickness of the insulation layer IL1 to be non-uniform, for example, the total thickness variation (TTV) of the insulation layer IL1 is greater than 10 μm (as shown by the total thickness variation TTV1 in FIG. 3). In this context, TTV refers to the maximum variation in the overall thickness of the layer (i.e., maximum thickness - minimum thickness), such that the flatness of the layer may be determined by measuring the thickness uniformity of the layer. In this embodiment, by disposing the planarization layer 110 on the insulation layer IL1, the insulation layer IL3 and the wiring structure WS3 in the third circuit structure CS3 may be formed on a surface with a total thickness variation TTV2 smaller than the total thickness variation TTV1, thereby helping to enhance the reliability of the electronic device 10. In this embodiment, the fillers FL1 may include inorganic fillers, such as oxides (e.g., silicon oxides or aluminum oxides). In some embodiments, the insulation layer IL1 may include a first material layer IL11 and a second material layer IL12. The first material layer IL11 may be an organic insulation layer containing fillers FL1, while the second material layer IL12 may be an organic insulation layer with a particle size smaller than the first material layer IL11 or without fillers FL1. In some embodiments, the wiring layer WS11 in the wiring structure WS1 may be formed in the first material layer IL11, while the wiring layer WS12 in the wiring structure WS1 may be formed in the first material layer IL12.

In some embodiments, as shown in FIGS. 1 and 2, the planarization layer 110 may also include a conductive element 112 electrically connecting and/or thermally coupling the first circuit structure CS1 to the third circuit structure CS3. The conductive element 112 may include a conductor material (e.g., metal material) with good electrical conductivity and thermal conductivity. In some embodiments, as shown in FIG. 3, the wiring structure WS1 of the first circuit structure CS1 and the wiring structure WS3 of the third circuit structure CS3 may also include portions formed in the planarization layer 110 to form the conductive element 112 shown in FIGS. 1 or 2.

In some embodiments, the planarization layer 110 may include a material with a dissipation factor (Df) at 10 GHz greater than or equal to 0.0002 and less than or equal to 0.03, to help enhance the reliability of the interposer 100. In some embodiments, the planarization layer 110 may include a material with a dielectric constant at 10 GHz greater than or equal to 2.6 and less than or equal to 7.0, to help enhance the reliability of the interposer 100. For example, the planarization layer 110 may include tetraethyl orthosilicate (TEOS), parylene, silicon oxide, silicon nitride, siloxane, PI, spin-on glass (SOG), BCB, or combinations thereof.

In some embodiments, the material of the planarization layer 110 may have at least one functional group capable of forming a covalent bond with the material of the insulation layer IL1 of the first circuit structure CS1, which can enhance the adhesion of the planarization layer 110 bonded to the insulation layer IL1 of the first circuit structure CS1, thereby enhancing the reliability of the interposer 100. In some embodiments, the above functional group may include an epoxy group, an amino group (-NH₂), a carbamoyl amino group (-NH-CO-NH₂), a vinyl carbonate group (-OCOCH=CH₂), or a thiol group (-SH). In some embodiments, the above functional group may be formed by providing an adhesion promoter to the planarization layer 110. In this embodiment, the adhesion promoter may include a silane coupling agent, such as 3-glycidoxypropyltrimethoxysilane (GPTMS, corresponding to the functional group of epoxy group), 3-acryloxypropyltrimethoxysilane (APTMS, corresponding to the functional group of -NH₂), γ-methacryloxypropyltriethoxysilane (UPTES, corresponding to the functional group of -NH-CO-NH₂), 3-(meth)acryloxypropyltrimethoxysilane (MPTS, corresponding to the functional group of -OCOCH=CH₂), mercaptopropyltrimethoxysilane (MPTMS, corresponding to the functional group of -SH), or combinations thereof.

In some embodiments, as shown in FIG. 4, the planarization layer 210 may include a first layer 210a adjacent to the first circuit structure CS1 and a second layer 210b on the first layer 210a and adjacent to the third circuit structure CS3, wherein the material of the second layer 210b may be different from that of the first layer 210a. For example, when the insulation layer IL1 includes an organic insulation layer and the insulation layer IL3 includes an inorganic insulation layer, the first layer 210a of the planarization layer 210 may include an organic insulation material, and the second layer 210b of the planarization layer 210 may include an inorganic insulation material, but is not limited thereto.

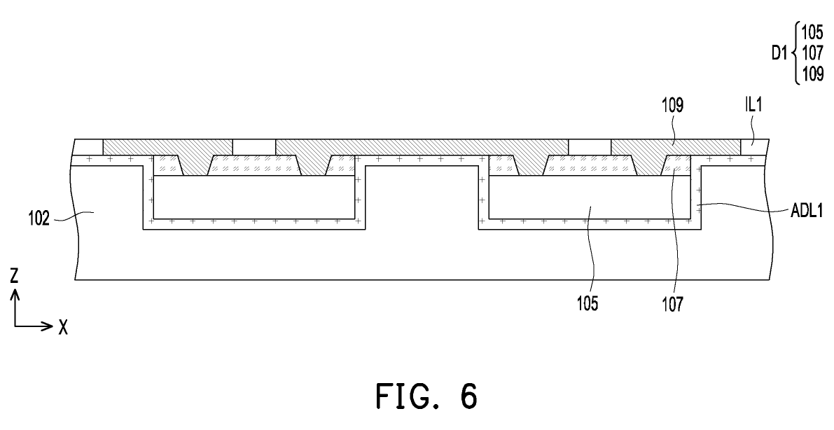

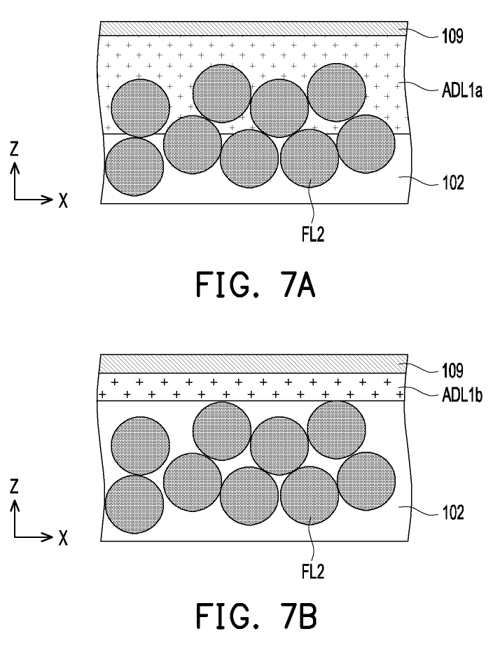

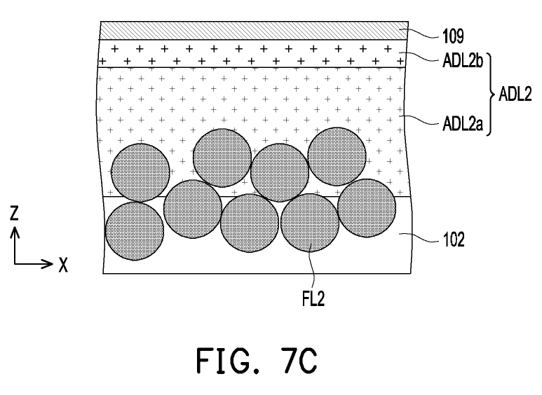

FIG. 5 is a schematic cross-sectional view illustrating an electronic device according to another embodiment of the present disclosure. FIG. 6 is a schematic enlarged cross-sectional view showing the electronic element and the adhesive layer of FIG. 5 according to an embodiment of the present disclosure. FIGS. 7A to 7C are schematic enlarged cross-sectional views of the adhesive layer shown in FIG. 5 according to various embodiments. The electronic device 10' shown in FIG. 5 is similar to the electronic device 10 shown in FIG. 1, and the difference is that the electronic device 10' includes an electronic element D1 disposed in the connection substrate SUB1, and other identical or similar components are denoted by identical or similar reference numerals, which will not be repeated herein.

Referring to FIGS. 5 and 6, the interposer 100 of the electronic device 10' may include an electronic element D1 disposed in the substrate layer 102 and an adhesive layer ADL1 disposed between the electronic element D1 and the substrate layer 102 and between the substrate layer 102 and the insulation layer IL1 of the first circuit structure CS1. In some embodiments, the electronic element D1 may be, for example, a known good die (KGD), a diode, an antenna unit, a sensor, a structure formed by semiconductor-related processes, or a component in which a structure formed by semiconductor-related processes is disposed on a base layer (e.g., a base layer including substrate materials such as polyimide, glass, silicon substrate, etc.), but is not limited thereto. In this embodiment, the electronic element D1 may include a base layer 105 and a circuit layer including an insulation layer 107 and a wiring layer 109. The insulation layer 107 may include any suitable insulation material. The wiring layer 109 may include any suitable conductive material.

In some embodiments, the material of the adhesive layer ADL1 may have at least one functional group capable of forming a covalent bond with the material of the insulation layer IL1 of the first circuit structure CS1 and/or the material of the substrate layer 102, so as to enhance the adhesion of the substrate layer 102 bonded to the insulation layer IL1 of the first circuit structure CS1, thereby enhancing the reliability of the interposer 100. In some embodiments, the above functional group may include an epoxy group, an amino group (-NH₂), a carbamoyl amino group (-NH-CO-NH₂), a vinyl carbonate group (-OCOCH=CH₂), or a thiol group (-SH). In some embodiments, the above functional group may be formed by providing an adhesion promoter to the adhesive layer ADL1. In this embodiment, the adhesion promoter may include a silane coupling agent, such as GPTMS (corresponding to the functional group of epoxy group), APTMS (corresponding to the functional group of -NH₂), UPTES (corresponding to the functional group of -NH-CO-NH₂), MPTS (corresponding to the functional group of -OCOCH=CH₂), MPTMS (corresponding to the functional group of -SH), or a combination thereof.

In other embodiments, the adhesive layer ADL1 may also be subjected to an oxygen plasma treatment (O₂ plasma treatment) or an ultraviolet ozone irradiation treatment to generate functional groups capable of increasing hydrophilicity (e.g., hydrophilic functional groups such as -OH or -C=O) on its surface, so as to improve the adhesion between inorganic materials and organic materials. In other embodiments, the adhesive layer ADL1 may also be subjected to a nitrogen plasma treatment (N₂ plasma treatment) to generate functional groups (such as NH₄⁺) capable of forming a covalent bond with the insulation layer IL1 and/or the substrate layer 102 on its surface, so as to enhance the adhesion strength.

In some embodiments, as shown in FIG. 7A, the adhesive layer ADL1 may be an organic adhesive layer ADL1a, such that even if the fillers FL2 in the substrate layer 102 partially moves to the organic adhesive layer ADL1a during the bonding process, it can maintain the flatness of the surface on which the wiring layer 109 is formed, thereby reducing the risk caused by the wiring layer 109 being formed on an uneven surface. In other embodiments, as shown in FIG. 7B, the adhesive layer ADL1 may be an inorganic adhesive layer ADL1b, such that the fillers FL2 in the substrate layer 102 may be prevented from moving to the inorganic adhesive layer ADL1b during the bonding process, thereby maintaining the flatness of the surface on which the wiring layer 109 is formed and reducing the risk caused by the wiring layer 109 being formed on an uneven surface. In other embodiments, as shown in FIG. 7C, the adhesive layer ADL2 may include an organic adhesive layer ADL2a formed on the substrate layer 102 and an inorganic adhesive layer ADL2b formed on the organic adhesive layer ADL2a, such that the adhesive layer ADL2 may have the above advantages, thereby further enhancing the reliability of the interposer 100.

In summary, in the embodiments of the present disclosure, each of the first circuit structure and the second circuit structure includes a second wiring structure thermally coupled to each other through a second through via among the plurality of through vias, and the first heat dissipation element disposed on the side surface of the interposer contacts and is thermally coupled to the second wiring structure and the second through via, which can help enhance the heat dissipation efficiency of the electronic device.

The foregoing embodiments are merely used to illustrate the technical solutions of the disclosure, and the embodiments are not limitations of the disclosure. Although the disclosure has been described in detail with reference to the foregoing embodiments, persons skilled in the art should understand that they may still modify the technical solutions recorded in the foregoing embodiments, or make equivalent substitutions for some or all of the technical features thereof; and these modifications or substitutions do not cause the essence of the corresponding technical solutions to depart from the scope of the technical solutions of the embodiments of the disclosure, and the features between embodiments may be arbitrarily mixed and matched for use as long as they do not violate the spirit of the invention or conflict with each other.

What is claimed is:

1. An electronic device, comprising:
an interposer, comprising:
a connection substrate, comprising a substrate layer and through vias penetrating through a first surface and a second surface of the substrate layer opposite to each other in a first direction; and
a first circuit structure and a second circuit structure, respectively disposed on the first surface and the second surface and each comprising a first wiring structure electrically connected to each other through at least one first through via among the through vias and a second wiring structure thermally coupled to each other through at least one second through via among the through vias;
at least one electronic unit, disposed on and electrically connected to the interposer; and
a first heat dissipation element, disposed on side surfaces of the interposer opposite to each other in a second direction different from the first direction, and being in contact with and thermally coupled to the second wiring structure and the second through via, wherein the first heat dissipation element comprises a heat dissipation layer and an adjustment layer,
wherein the adjustment layer is disposed between the heat dissipation layer and the interposer in the second direction, and a heat transfer coefficient of the heat dissipation layer is greater than a heat transfer coefficient of the adjustment layer.

2. The electronic device of claim 1, wherein each of the first circuit structure and the second circuit structure comprises an insulation layer in which the first wiring structure and the second wiring structure are disposed, and the side surfaces of the interposer are configured at side surfaces of the insulation layer.

3. The electronic device of claim 2, wherein a thermal expansion coefficient of the adjustment layer is less than a thermal expansion coefficient of the interposer.

4. The electronic device of claim 1, wherein a thickness of the heat dissipation layer in the second direction is greater than a thickness of the adjustment layer in the second direction.

5. The electronic device of claim 1, further comprising:
an external component, disposed below and electrically connected to the interposer; and
a heat dissipation member, disposed on and thermally coupled to the electronic unit.

6. The electronic device of claim 5, further comprising:
a stiffener, surrounding the side surfaces of the interposer and disposed between the heat dissipation member and the external component in the first direction, wherein the first heat dissipation element is disposed between the stiffener and the interposer in the second direction.

7. The electronic device of claim 5, further comprising:
bonding elements, disposed between the interposer and the external component and comprising at least one first bonding element electrically connecting the first wiring structure of the second circuit structure to the external component and at least one second bonding element thermally coupling the second wiring structure of the second circuit structure to the external component.

8. The electronic device of claim 7, wherein the second bonding element comprises a portion overlapping the first heat dissipation element in the first direction.

9. The electronic device of claim 1, wherein each of the first circuit structure and the second circuit structure comprises an insulation layer in which the first wiring structure and the second wiring structure are disposed, the second wiring structure comprises a heat dissipation layer and a heat dissipation via that are disposed in the insulation layer, thermally coupled to each other, and each comprises a sidewall exposed at the side surface of the interposer.

10. The electronic device of claim 9, wherein the interposer comprises a third circuit structure disposed above the first circuit structure and comprising a third wiring structure electrically connecting the electronic unit to the first wiring structure of the first circuit structure and a fourth wiring structure thermally coupled to the second wiring structure of the first circuit structure.

11. The electronic device of claim 10, wherein the fourth wiring structure is in contact with and thermally coupled to the first heat dissipation element, and a pitch of the third wiring structure is smaller than a pitch of the first wiring structure.

12. The electronic device of claim 11, wherein the interposer comprises a planarization layer disposed between the third circuit structure and the first circuit structure.

13. The electronic device of claim 12, wherein the planarization layer comprises a first layer adjacent to the first circuit structure and a second layer on the first layer and adjacent to the third circuit structure, and a material of the second layer is different from a material of the first layer.

14. The electronic device of claim 12, wherein a material of the planarization layer has at least one functional group capable of forming a covalent bond with a material of the insulation layer of the first circuit structure.

15. The electronic device of claim 14, wherein the functional group comprises an epoxy group, an amino group, a carbamoyl amino group, a vinyl carbonate group, or a thiol group.

16. The electronic device of claim 15, wherein the material of the planarization layer has a dissipation factor greater than or equal to 0.0002 and less than or equal to 0.03 at 10 GHz.

17. The electronic device of claim 15, wherein the material of the planarization layer has a dielectric constant greater than or equal to 2.6 and less than or equal to 7.0 at 10 GHz.

18. The electronic device of claim 9, wherein the interposer comprises an electronic element disposed in the substrate layer and an adhesive layer disposed between the electronic element and the substrate layer and between the substrate layer and the insulation layer of the first circuit structure, and a material of the adhesive layer has at least one functional group capable of forming a covalent bond with a material of the insulation layer of the first circuit structure and/or a material of the substrate layer, wherein the functional group comprises an epoxy group, an amino group, a carbamoyl amino group, a vinyl carbonate group, or a thiol group.
